(19) United States
(12) Patent Application Publication
(10) Pub. No.: US 2017/0310106 A1
(43) Pub. Date: Oct. 26, 2017

(54) SYSTEM FOR DETECTING AND CONTROLLING ABNORMAL STATE OF ELECTRIC SIGNAL AND METHOD THEREOF

(71) Applicant: CESIGN CO., LTD., Seongnam-si (KR)

(72) Inventors: Soo Hyoung LEE, Hwaseong-si (KR); Justin Jungsup KIM, Yongin-si (KR); Jeong Pyo Kim, Yongin-si (KR)

(21) Appl. No.: 15/406,986

(22) Filed: Jan. 16, 2017

(30) Foreign Application Priority Data
Apr. 21, 2016 (KR) 10-2016-0048707

(51) Int. Cl. H02J 3/00; G01R 31/02; G01R 19/00

(52) U.S. Cl. CPC H02J 3/00; G01R 19/0038; G01R 31/02

(57) ABSTRACT

A system for detecting and controlling an abnormal state of an electrical signal, includes: an abnormality decision part determining whether or not an electrical signal detected from a power line is abnormal by using the electrical signal and generating a control signal for controlling ON/OFF of N switches included in a leakage breaker. The system for detecting and controlling the abnormal state of the electrical signal is capable of controlling an operation of the leakage breaker by using voltage and current signals detected from the power line through which commercial power is supplied and functioning as a black box when an accident occurs such as a fire, etc.

### CROSS REFERENCE TO RELATED APPLICATION

The present application claims priority to Korean Patent Application No. 10-2016-0048707, filed Apr. 21, 2016, the entire contents of which is incorporated herein for all purposes by this reference.

### BACKGROUND OF THE INVENTION

### Field of the Invention

The present invention generally relates to a system for detecting and controlling an abnormal state of an electrical signal and a method thereof that are capable of determining the abnormal state by detecting the electric signal from a power line and controlling ON/OFF of power supplied to a load, according to the detected electric signal.

### Description of the Related Art

Korean Patent Application Publication No. 10-2015-0102558 (Method for measuring power of power measurement apparatus, hereinafter, related art document 1) discloses a method of measuring power of a power measurement apparatus, the method capable of easily measuring power through a combination with various other apparatuses, accurately measuring power data without additional equipment by correcting a phase difference between a current and a voltage in a power measurement step, accurately and reliably measuring the power with regard to a load in use, and accurately measuring the power data by measuring active power and reactive power by correcting the phase difference between the voltage and the current in the power measurement step.

In addition, Korean Patent No. 10-1422420 (Reset type power switch that includes ELB auto recovery function, hereinafter, related art document 2) discloses a reset type power switch including an auto recovery function of a leakage breaker including a load switch box in which, when a trip occurs due to lightening, a surge, or a short circuit, a state of a load is analyzed so that the leakage breaker is automatically recovered under normal conditions of the load, and signals output from a plurality of toggle switch output terminals including multiple terminals are recognized so that the plurality of toggle switches are respectively reset when an abnormal signal occurs.

However, when a chip for measuring power that is referred to an energy metering chip and implemented by applying the related art document 1 is implemented to include the same function of the related art document 2, it may be possible to implement a more efficient system that a conventional one for detecting and controlling an abnormal state of an electrical.

The foregoing is intended merely to aid in the understanding of the background of the present invention, and is not intended to mean that the present invention falls within the purview of the related art that is already known to those skilled in the art.

### DOCUMENTS OF RELATED ART

(Patent Document 1) Korean Patent Application Publication No. 10-2015-0102558
(Patent Document 2) Korean Patent No. 10-1422420

### SUMMARY OF THE INVENTION

Accordingly, the present invention has been made keeping in mind the above problems occurring in the related art, and the present invention is intended to propose a system for detecting and controlling an abnormal state of an electrical signal and a method thereof that are capable of controlling operation of a leakage breaker by using a voltage signal and a current signal that are sensed from a power line in which commercial power is supplied.

In addition, another object of the present invention is to provide a system for detecting and controlling an abnormal state of an electrical signal and a method thereof that are capable of functioning as a black box when an accident occurs such as a fire, etc.

In order to achieve the above object, according to one aspect of a preferred embodiment of the present invention, there is provided a system for detecting and controlling an abnormal state of an electrical signal, the system including: an abnormality decision part determining whether or not an electrical signal detected from a power line is abnormal by using the electrical signal and generating a control signal for controlling ON/OFF of N switches included in a leakage breaker.

In detail, the abnormality decision part may classify the electrical signal detected from the power line by using a first energy level and a second energy level into: a first section when the detected electrical signal is equal to or greater than the first energy level; a second section when the detected electrical signal is less than the first energy level and is equal to or greater than the second energy level; and a third section when the detected electrical signal is less than the second energy level.

In addition, when the electrical signal detected from the power line is classified to the first section, the abnormality decision part may generate control signals to switch off M switches among the N switches of the leakage breaker and blocks power of the power line that passes through the M switches of the leakage breaker, M being a natural number that is equal to or less than N. In addition, when the electrical signal detected from the power line is classified to the second section, the abnormality decision part may generate control signals to switch off K switches among N switches of the leakage breaker and blocks power of the power line that passes through the K switches of the leakage breaker. K may be a natural number that is less than M. In other words, the abnormality decision part may classify the electrical signal detected from the power line into multiple sections and generate control signals capable of switching off a number of switches among the N switches of the leakage breaker for each section, the numbers of switches switched off for respective sections being different from each other. In addition, the abnormality decision part may generate a control signal that switches on at least a part of the N switches of the leakage breaker for all multiple classified sections.

When the electrical signal detected from the power line is firstly classified to the second section, but is changed to the third section and maintained in the third section for a first predetermined time or more, the abnormality decision part may generate control signals to switch on all the N switches of the leakage breaker and supply power to the power line that passes through the N switches of the leakage breaker. In addition, when the electrical signal detected from the power line is firstly classified to the first section but is changed to the third section and maintained in the third section for a second predetermined time or more, the abnormality decision part may generate control signals to switch on all the N switches of the leakage breaker and supply power to the power line that passes through the N switches of the leakage breaker.

In addition, when the electrical signal detected from the power line satisfies a preset condition, the system may store corresponding information in a memory. Herein, when the electrical signal detected from the power line and classified to the second section by the abnormality decision part is maintained in the second section for a third predetermined time or more, or is classified to the second section at least a predetermined frequency during a fourth predetermined time, the electrical signal detected from the power line may satisfy the preset condition.

According to another aspect, there is provided a method of detecting and controlling an abnormal state of an electrical signal, the method including: a step (a) of determining whether or not an electrical signal detected from a power line is abnormal and generating a control signal for controlling ON/OFF of N switches included in a leakage breaker and a step (b) of storing corresponding information in a memory when the electrical signal detected from the power line satisfies a preset condition.

In detail, the step (a) may include: a step (a-1) of classifying the electrical signal detected from the power line by using a first energy level and a second energy level into: a first section when the electrical signal detected from the power line is equal to or greater than the first energy level; a second section when the electrical signal detected from the power line is less than the first energy level and is equal to or greater than the second energy level; and a third section when the electrical signal detected from the power line is less than the second energy level. In addition, when the electrical signal detected from the power line is classified to the first section in the step (a-1), the step (a) may further include a step (a-2) of generating control signals to switch off M switches among the N switches of the leakage breaker and blocking power of the power line that passes through the M switches of the leakage breaker. In addition, when the electrical signal detected from the power line is classified to the second section in the step (a-1), the step (a) may further include a step (a-3) of generating control signals to switch off K switches among the N switches of the leakage breaker and blocking power of the power line that passes through the K switches of the leakage breaker.

Here, M may be a natural number that is equal to or less than N, and K may be a natural number that is less than M.

In addition, when the electrical signal detected from the power line is firstly classified to the second section but is changed to the third section and maintained in the third section for a first predetermined time or more, the step (a) may further include a step (a-4) of generating control signals to switch on all the N switches of the leakage breaker and supplying power to the power line that passes through the N switches of the leakage breaker. Further, when the electrical signal detected from the power line is firstly classified to the first section but is changed to the third section and maintained in the third section for a second predetermined time or more, the step (a) may further include a step (a-5) of generating control signals to switch on all the N switches of the leakage breaker and supplying power to the power line that passes through the N switches of the leakage breaker. In other words, the step (a) may classify the electrical signal detected from the power line into multiple sections and generate control signals capable of switching off a number of switches among the N switches of the leakage breaker, the numbers of switches switched off for respective sections being different from each other. In addition, the step (a) may generate a control signal that switches on at least a part of the N switches of the leakage breaker for all multiple classified sections.

In addition, when the electrical signal detected from the power line and classified to the second section by the abnormality decision part is maintained in the second section for a third predetermined time or more, or is classified to the second section at least a predetermined frequency during a fourth predetermined time, the electrical signal detected from the power line may satisfy the preset condition of the step (b).

The system for detecting and controlling the abnormal state of the electrical signal and the method thereof according to the present invention are capable of controlling the operation of the leakage breaker by using voltage and current signals sensed from the power line in which the commercial power is supplied and of functioning as a black box when an accident occurs such as a fire, etc.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a view showing an arrangement of a system for detecting and controlling an abnormal state of an electrical signal according to a preferred embodiment of the present invention;

FIG. 2 is a configuration diagram of a leakage breaker;

FIG. 3 is a configuration diagram of the system for detecting and controlling an abnormal state of the electrical signal according to the preferred embodiment of the present invention; and

FIG. 4 is a view showing a configuration of an abnormality decision part.

### DETAILED DESCRIPTION OF THE INVENTION

Hereinbelow, exemplary embodiments of the present invention will be described in detail with reference to the accompanying drawings.

The present invention may be embodied in many different forms without departing from the spirit and significant characteristics of the invention. Therefore, the embodiments of the present invention are disclosed only for illustrative purposes and should not be construed as limiting the present invention.

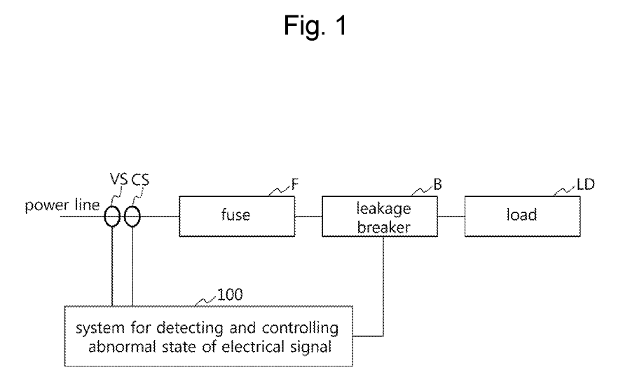

First, FIG. 1 is a view showing an arrangement of a system 100 for detecting and controlling an abnormal state of an electrical signal according to a preferred embodiment of the present invention.

As shown in FIG. 1, the system 100 for detecting and controlling the abnormal state of the electrical signal according to the preferred embodiment of the present invention may determine whether or not a power state of a power line is abnormal by using the electrical signal detected by a voltage sensor VS and a current sensor CS that are provided in the power line through which commercial power is supplied, and the system 100 for detecting and controlling the abnormal state of the electrical signal may also control an operation of a leakage breaker B.

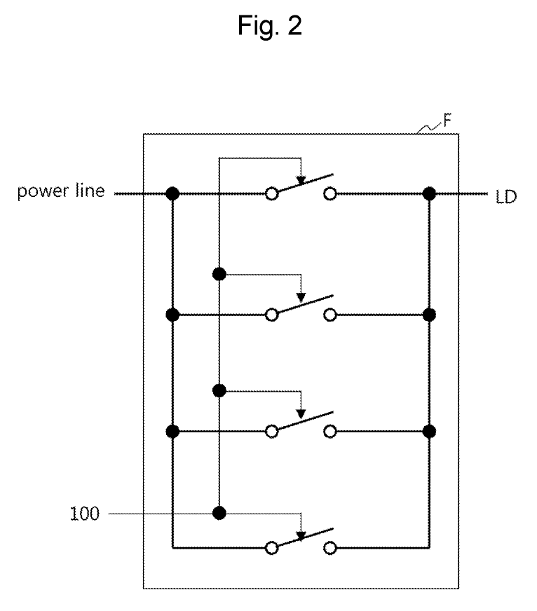

In addition, as shown in FIG. 2, the leakage breaker B may include N switches. Herein, inputs and outputs of the N switches may be respectively connected to a single input and to a single output. In other words, the inputs of the N switches are connected to the power line by passing a fuse F, and the outputs of the N switches are added to each other and connected to a load LD.

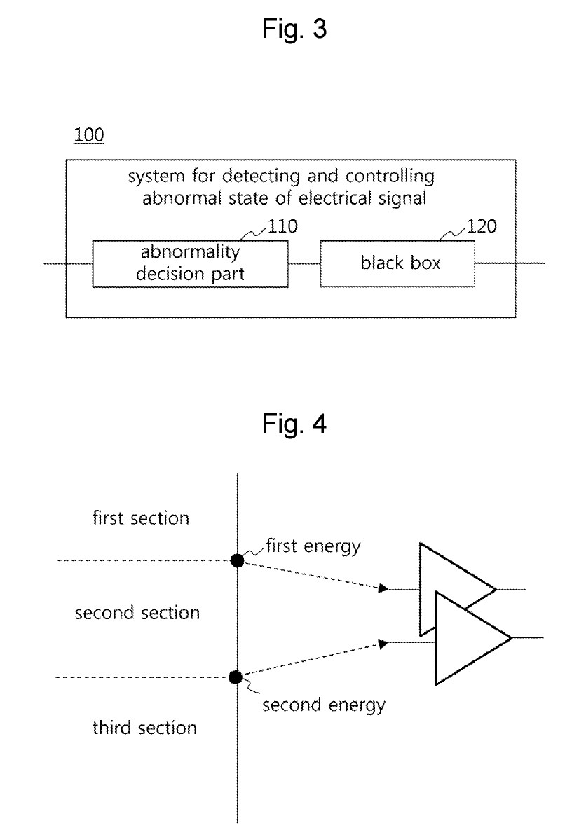

FIG. 3 is a configuration diagram of the system 100 for detecting and controlling the abnormal state of the electrical signal according to the preferred embodiment of the present invention.

As shown in the FIG. 3, the system 100 for detecting and controlling the abnormal state of the electrical signal according to the preferred embodiment of the present invention may include an abnormality decision part 110 and a black box 120.

The abnormality decision part 110 functions to determine whether or not the electrical signal is abnormal by using the electrical signal detected from the power line. In other words, when amplitudes of a voltage signal and a current signal respectively sensed by the voltage sensor VS and the current sensor CS that detect voltages and currents of the power line through which the commercial power is supplied belong to a leakage warning section or to a definite leakage section, then a comparator of the abnormality decision part 110 is operated to inform the abnormal state of a present voltage and a present current, and a signal that is output from the comparator functions to generate a control signal for controlling the leakage breaker B.

FIG. 4 is a view showing a configuration of an abnormality decision part 110.

As shown in FIG. 4, the abnormality decision part 110 of the present invention may include two comparators.

In other words, the abnormality decision part 110 of the present invention sets a first energy level and a second energy level as respective reference signals of the comparators. The abnormality decision part 110 classifies the electrical signal detected from the power line into three sections by comparing with the first energy level and the second energy level. Herein, the electrical signal detected from the power line includes a voltage signal and a current signal that are detected by using the voltage sensor VS and the current sensor CS.

Herein, the electrical signal is classified into three sections by using the following criteria.
First section: when the electrical signal detected from the power line is equal to or greater than the first energy level.
Second section: when the electrical signal detected from the power line is less than the first energy level and is equal to and greater than the second energy level.
Third section: when the electrical signal detected from the power line is less than the second energy level.

In detail, the first section means that the electrical signal belongs to a definite leakage section, the second section means that the electrical signal belongs to a leakage warning section, and the third section means that the electrical signal belongs to a normal section.

In addition, the abnormality decision part 110 generates a control signal for controlling ON/OFF of N switches that are provided in the leakage breaker B by using the electrical signal that is classified into three sections.

In detail, when the electrical signal detected from the power line through which the commercial power is supplied is classified to the first section, the abnormality decision part 110 may generate control signals to switch off M switches B among the N switches of the leakage breaker B and block power of the power line that passes through the M switches of the leakage breaker B. Herein, M is a natural number that is equal to or less than N.

In addition, when the electrical signal detected from the power line is classified to the second section, the abnormality decision part 110 generates control signals to switch off K switches B among the N switches of the leakage breaker B and blocks power of the power line that passes through the K switches of the leakage breaker B. Herein, K is a natural number that is less than M.

In other words, the abnormality decision part 110 classifies the electrical signal detected from the power line into multiple sections and generates control signals capable of switching off a number of switches among the N switches of the leakage breaker B for each section, the numbers of switches switched off for respective sections is different from each other. In addition, the abnormality decision part 110 may generate a control signal that switches on at least a part of the N switches of the leakage breaker B for all multiple classified sections.

In other words, according to the present invention, the number of switches switched off in the first section, which means that the electrical signal belongs to the definite leakage section is greater than the number of switches switched off in the second section, which means that the electrical signal belongs to the leakage warning section. Further, all the N switches are switched on when the electrical signal belongs to the third section, which means that the electrical signal belongs to the normal section, thus the power supplied to the load LD may be stepwisely controlled.

Meanwhile, all the N switches may be switched off in the first section, which means that the electrical signal belongs to the definite leakage state to block a power supplement to the load LD. However, the abnormality decision part 110 may switch on a part of the N switches of the leakage breaker B to supply the minimum power to the load LD such that the load LD uses the minimum power as emergency power.

In addition, when the electrical signal detected from the power lines belongs to the second section, a warning signal may be transmitted to a user terminal such that the user may take an appropriate action.

In addition, when the electrical signal detected from the power line is firstly classified to the second section, but is changed to the third section and maintained in the third section for a first predetermined time or more, the abnormality decision part 110 of the present invention may generate control signals to switch on all the N switches of the leakage breaker B and supplies the power to the power line that passes through the N switches of the leakage breaker B. Similarly, when the electrical signal detected from the power line is firstly classified to the first section, but is changed to the third section and maintained in the third section for a second predetermined time or more, the abnormality decision part 110 may generate control signals to switch on all the N switches of the leakage breaker B and supplies the power to the power line that passes through the N switches of the leakage breaker B. Thus, the user does not need to manually operate the leakage breaker B by an automatic reset function thereof.

When the electrical signal detected from the power line satisfies a preset condition, the black box 120 of the present invention functions as a black box by storing corresponding information in a memory.

In other words, the black box 120 may be implemented by using a register included in an energy metering chip and store signal information of the abnormal state that is transmitted from the abnormality decision part 110. For example, 1.2 kBytes is enough to store the signal information through which the voltage and the current are sensed 10 times per minute for about 1 hour and 20 bits is used for each storing. A large effect may be obtained by using a small memory.

The user may easily detect a cause of the abnormal state of the electrical signal by analyzing the signal information stored by the black box 120.

Herein, when the electrical signal detected from the power line and classified to the second section by the abnormality decision part is maintained in the second section for a third predetermined time or more, or is classified to the second section at least a predetermined frequency during a fourth predetermined time, the electrical signal detected from the power line satisfies the preset condition.

In other words, the abnormality decision part 110 determines that the electrical signal detected from the power line is abnormal when the electrical signal classified to the second section is not recovered to the third section that is the normal state within a short period of time, or when the electrical signal is transited to the second section several times.

The system 100 for detecting and controlling the abnormal state of the electrical signal of the present invention may be implemented by being integrated in the energy metering chip. Generally, the energy metering chip is provided in a front of the leakage breaker B and the fuse F, so the energy metering chip is capable of continuously checking whether or not the power state of the power line through which the commercial power is supplied is abnormal even though the leakage breaker B and the fuse F are disconnected.

Hereinafter, a method of detecting and controlling an abnormal state of an electrical signal according to a preferred embodiment of the present invention will be described. Since the method of detecting and controlling the abnormal state of the electrical signal according to the preferred embodiment of the present invention uses the system 100 for detecting and controlling the abnormal state of the electrical signal according to the present invention that is described above, the method includes all features of the system 100 for detecting and controlling the abnormal state of the electrical signal although there is no explanation.

The method of detecting and controlling the abnormal state of the electrical signal according to the preferred embodiment of the present invention may include a step (a) of determining whether or not an electrical signal detected from a power line is abnormal and generating a control signal for controlling ON/OFF of N switches included in a leakage breaker B, and a step (b) of storing corresponding information in a memory when the electrical signal detected from the power line satisfies a preset condition.

In detail, the step (a) includes: a step (a-1) of classifying the electrical signal detected from the power line by using a first energy level and a second energy level into: a first section when the electrical signal detected from the power line is equal to or greater than the first energy level; a second section when the electrical signal detected from the power line is less than the first energy level and is equal to or greater than the second energy level; and a third section when the electrical signal detected from the power line is less than the second energy level.

In addition, when the electrical signal detected from the power line is classified to the first section in the step (a-1), the step (a) may further include a step (a-2) of generating control signals to switch off M switches among the N switches of the leakage breaker B and blocking power of the power line that passes through the M switches of the leakage breaker B. Alternatively, when the electrical signal detected from the power line is classified to the second section in the step (a-1), the step (a) may further include a step (a-3) of generating control signals to switch off K switches among the N switches of the leakage breaker B and blocking power of the power line that passes through the K switches of the leakage breaker B.

Herein, M is a natural number that is equal to or less than N, and the K is a natural number that is less than M.

In other words, in the step (a), the electrical signal detected from the power line is classified into multiple sections, and control signals capable of switching off a number of switches among the N switches of the leakage breaker B are generated, the numbers of switches switched off for respective sections being different from each other. In addition, the step (a) may generate a control signal that switches on at least a part of the N switches of the leakage breaker B for all multiple classified sections.

In addition, when the electrical signal detected from the power line is firstly classified to the second section but is changed to the third section and maintained in the third section for a first predetermined time or more, the step (a) further includes a step (a-4) of generating control signals to switch on all the N switches of the leakage breaker B and supplying power to the power line that passes through the N switches of the leakage breaker B. In addition, when the electrical signal detected from the power line is firstly classified to the first section but is changed to the third section and maintained in the third section for a second predetermined time or more, the step (a) further includes a step (a-5) of generating control signals to switch on all the N switches of the leakage breaker B and supplying power to the power line that passes through the N switches of the leakage breaker B.

In addition, when the electrical signal detected from the power line and classified to the second section in the step (a) is maintained in the second section for a third predetermined time or more, or is classified to the second section at least a predetermined frequency during a fourth predetermined time, the electrical signal detected from the power line satisfies the preset condition.

As described above, the system 100 for detecting and controlling the abnormal state of the electrical signal and the method thereof according to the present invention are capable of controlling the operation of the leakage breaker B by using current signal and the voltage signals sensed from the power line through which the commercial power is supplied and functioning as the black box when an accident occurs such as a fire, etc.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A system for detecting and controlling an abnormal state of an electrical signal, the system comprising:
an abnormality decision part determining whether or not an electrical signal detected from a power line is abnormal by using the electrical signal and generating a control signal for controlling ON/OFF of N switches included in a leakage breaker.

2. The system of claim 1, wherein the abnormality decision part classifies the electrical signal detected from the power line by using a first energy level and a second energy level into:
a first section when the detected electrical signal is equal to or greater than the first energy level;
a second section when the detected electrical signal is less than the first energy level and is equal to or greater than the second energy level; and
a third section when the detected electrical signal is less than the second energy level.

3. The system of claim 2, wherein when the electrical signal detected from the power line is classified to the first section, the abnormality decision part generates control signals to switch off M switches among the N switches of the leakage breaker and blocks power of the power line that passes through the M switches of the leakage breaker, M being a natural number that is equal to or less than N.

4. The system of claim 3, wherein when the electrical signal detected from the power line is classified to the second section, the abnormality decision part generates control signals to switch off K switches among the N switches of the leakage breaker and blocks power of the power line that passes through the K switches of the leakage breaker, K being a natural number that is less than M.

5. The system of claim 4, wherein when the electrical signal detected from the power line is firstly classified to the second section, but is changed to the third section and maintained in the third section for a first predetermined time or more, the abnormality decision part generates control signals to switch on all the N switches of the leakage breaker and supplies power to the power line that passes through the N switches of the leakage breaker.

6. The system of claim 5, wherein when the electrical signal detected from the power line is firstly classified to the first section but is changed to the third section and maintained in the third section for a second predetermined time or more, the abnormality decision part generates control signals to switch on all the N switches of the leakage breaker and supplies power to the power line that passes through the N switches of the leakage breaker.

7. The system of claim 3, wherein when the electrical signal detected from the power line satisfies a preset condition, the system stores corresponding information in a memory.

8. The system of claim 7, wherein when the electrical signal detected from the power line and classified to the second section by the abnormality decision part is maintained in the second section for a third predetermined time or more, or is classified to the second section at least a predetermined frequency during a fourth predetermined time, the electrical signal detected from the power line satisfies the preset condition.

9. The system of claim 1, wherein the abnormality decision part classifies the electrical signal detected from the power line into multiple sections and generates control signals capable of switching off a number of switches among the N switches of the leakage breaker for each section, the numbers of switches switched off for respective sections being different from each other.

10. The system of claim 9, wherein the abnormality decision part generates a control signal that switches on at least a part of the N switches of the leakage breaker for all multiple classified sections.

11. A method of detecting and controlling an abnormal state of an electrical signal, the method comprising:
a step (a) of determining whether or not an electrical signal detected from a power line is abnormal and generating a control signal for controlling ON/OFF of N switches included in a leakage breaker.

12. The method of claim 11, wherein the step (a) includes:
a step (a-1) of classifying the electrical signal detected from the power line by using a first energy level and a second energy level into:
a first section when the electrical signal detected from the power line is equal to or greater than the first energy level;
a second section when the electrical signal detected from the power line is less than the first energy level and is equal to or greater than the second energy level; and
a third section when the electrical signal detected from the power line is less than the second energy level.

13. The method of claim 12, wherein when the electrical signal detected from the power line is classified to the first section in the step (a-1), the step (a) further includes a step (a-2) of generating control signals to switch off M switches among the N switches of the leakage breaker and blocking power of the power line that passes through the M switches of the leakage breaker, M being a natural number that is equal to or less than N.

14. The method of claim 13, wherein when the electrical signal detected from the power line is classified to the second section in the step (a-1), the step (a) further includes a step (a-3) of generating control signals to switch off K switches among the N switches of the leakage breaker and blocking power of the power line that passes through the K switches of the leakage breaker, K being a natural number that is less than M.

15. The method of claim 14, wherein when the electrical signal detected from the power line is firstly classified to the second section but is changed to the third section and maintained in the third section for a first predetermined time or more, the step (a) further includes a step (a-4) of generating control signals to switch on all the N switches of the leakage breaker and supplying power to the power line that passes through the N switches of the leakage breaker.

16. The method of claim 15, wherein when the electrical signal detected from the power line is firstly classified to the first section but is changed to the third section and maintained in the third section for a second predetermined time or more, the step (a) further includes a step (a-5) of generating control signals to switch on all the N switches of the leakage breaker and supplying power to the power line that passes through the N switches of the leakage breaker.

17. The method of claim 13, wherein when the electrical signal detected from the power line satisfies a preset condition, the method further includes a step (b) of storing corresponding information in a memory.

18. The method of claim 17, wherein when the electrical signal detected from the power line and classified to the second section by the abnormality decision part is maintained in the second section for a third predetermined time or more, or is classified to the second section at least a predetermined frequency during a fourth predetermined time, the electrical signal detected from the power line satisfies the preset condition.

19. The method of claim 11, wherein the step (a) classifies the electrical signal detected from the power line into multiple sections and generates control signals capable of switching off a number of switches among the N switches of the leakage breaker, the numbers of switches switched off for respective sections being different from each other.

20. The method of claim 19, wherein the step (a) generates a control signal that switches on at least a part of the N switches of the leakage breaker for all multiple classified sections.
